(19) United States
(12) Patent Application Publication
(10) Pub. No.: US 2022/0038057 A1
(43) Pub. Date: Feb. 3, 2022

(54) CLOSED LOOP POWER AMPLIFIER NONLINEARITY CONTROL

(71) Applicant: QUALCOMM Incorporated, San Diego, CA (US)

(72) Inventors: Igor GUTMAN, Ramat Gan (IL); Sharon LEVY, Binyamina (IL); Guy WOLF, Rosh Haayin (IL)

(21) Appl. No.: 16/942,638

(22) Filed: Jul. 29, 2020

(51) Int. Cl. H03F 1/02; H04W 52/52; H03F 3/195; H03F 3/24; H04B 17/13

(52) U.S. Cl. CPC H03F 1/0227; H04W 52/52; H04B 17/13; H03F 3/24; H03F 3/195

(57) ABSTRACT

Various aspects of the disclosure relate to a closed loop control of user equipment (UE) or base station (BS) power amplifier nonlinearity. One aspect provides a method of reporting an out-of-band power measurement by a UE in a wireless communication network. A UE may receive a downlink data traffic signal on a physical downlink channel from a base station. The UE may then measure an out of band (OOB) power of the received downlink data traffic signal, the receive OOB power comprising an average power of the downlink data traffic signal in one or more (OOB) locations of the wireless communication network offset from the physical downlink channel. The UE may then generate an OOB power measurement information element (IE) indicating the measured OOB power and send the OOB power measurement IE to the base station in an uplink control channel.

### TECHNICAL FIELD

The technology discussed below relates generally to wireless communication networks, and more particularly, to controlling a transmit power of a wireless transmitter power amplifier.

### Introduction

In fifth generation (5G) wireless communication networks, such as the New Radio (NR) wireless communication network, the utilization efficiency of radiated power is carefully controlled. Wireless transmitters typically include a radio frequency (RF) power amplifier (PA) for amplifying the RF signal with sufficient power for wireless transmission to remote devices via one or more antennas. Each PA is typically a non-linear device with a limited linear dynamic range (DR). The typical PA is more efficient when driven as close as possible to saturation. However, driving such a PA close to saturation causes the PA to operate outside its linear range, this can cause significant non-linear distortion. When power efficiency is important the distortion can be addressed by pre-distorting the RF signal before it is amplified.

### BRIEF SUMMARY OF SOME EXAMPLES

The following presents a summary of one or more aspects of the present disclosure, in order to provide a basic understanding of such aspects. This summary is not an extensive overview of all contemplated features of the disclosure and is intended neither to identify key or critical elements of all aspects of the disclosure nor to delineate the scope of any or all aspects of the disclosure. Its sole purpose is to present some concepts of one or more aspects of the disclosure in a form as a prelude to the more detailed description that is presented later.

Various aspects of the disclosure relate to a closed loop control of user equipment (UE) or base station (BS) power amplifier nonlinearity. One aspect provides a method of reporting an out-of-band power measurement by a UE in a wireless communication network. A UE may receive a downlink data traffic signal on a physical downlink channel from a base station. The UE may then measure an out of band (OOB) power of the received downlink data traffic signal, the receive OOB power comprising an average power of the downlink data traffic signal in one or more (OOB) locations of the wireless communication network offset from the physical downlink channel. The UE may then generate an OOB power measurement information element (IE) indicating the measured OOB power and send the OOB power measurement IE to the base station in an uplink control channel.

In one example, the UE further receives a second downlink data traffic signal on the physical downlink channel from the base station at the UE, wherein the second downlink data traffic signal has a different transmit power in response to the OOB power measurement IE. In another example, the UE further receives a request to transmit an OOB power measurement IE from the base station before receiving the downlink data traffic signal and wherein sending the OOB power measurement IE is in response to the received request. In another example, the request is transmitted in a downlink control channel when the UE is in a connected radio resource control (RRC) status.

In one example, the downlink data traffic signal is received when the UE is in a connected RRC status. One example includes sending the OOB power measurement IE with neighboring cell receive power measurements for handoff.

In another example measuring the OOB power further comprises determining a ratio of an average power of the downlink data traffic signal in the physical downlink channel divided by an average power leakage into out-of-band locations offset from the physical downlink channel. In one example the average power of the downlink data traffic signal comprises an average power of resource elements carrying physical downlink shared channel ports to the UE within a selected frequency width for a selected duration. In another example, the average power leakage into out-of-band locations comprises an average power in multiple out-of-band locations for the selected frequency width for the selected duration, the power in each location being scaled for a distance in frequency from a frequency of the downlink data traffic signal.

In another aspect determining the ratio comprises measuring the average power within a selected frequency range above and below a center frequency of the downlink data traffic signal and measuring the average power within the selected frequency range above and below the out-of-band locations, wherein the physical downlink channel has an allocated bandwidth, wherein the out-of-band locations are determined as a frequency distance from a frequency edge of the allocated bandwidth of the center frequency.

In another example, the measured average power in each of the multiple out-of-band locations is transmitted in the OOB power measurement IE. In another example, measuring the OOB power further comprises measuring in-band distortion of the downlink data traffic signal. In another example, measuring in-band distortion comprises measuring error vector magnitude.

Another aspect provides a user equipment (UE) in a wireless communication network that includes a wireless transceiver comprising a nonlinear power amplifier, a memory, and a processor communicatively coupled to the wireless transceiver and the memory. The processor is configured to receive a downlink data traffic signal on a physical downlink channel from a base station at the UE, measure an out of band (OOB) power of the received downlink data traffic signal, the receive OOB power comprising an average power of the downlink data traffic signal in one or more (OOB) locations of the wireless communication network offset from the physical downlink channel, generate an OOB power measurement information element (IE) indicating the measured OOB power, and send the OOB power measurement IE to the base station in an uplink control channel.

In one example the processor is further configured to receive a second downlink data traffic signal on the physical downlink channel from the base station at the UE, wherein the second downlink data traffic signal has a different transmit power in response to the OOB power measurement IE. In one example processor is further configured to receive a request to transmit an OOB power measurement IE from the base station before receiving the downlink data traffic signal and wherein sending the OOB power measurement IE is in response to the received request. In one example the request is transmitted in a downlink control channel when the UE is in a connected radio resource control (RRC) status.

Another aspect provides a method of controlling transmit power back off in a user equipment (UE) in a wireless communication network. The UE receives an uplink data traffic signal on a physical uplink channel from a UE at a base station, measures an out of band (OOB) power of the received uplink data traffic signal, the OOB power comprising an average power of the uplink data traffic signal in one or more OOB locations of the wireless communication network offset from the physical uplink channel, determines a power back for the UE using the measured OOB power, and sends a power back off information element (IE) to the UE in a downlink control channel, the power back off IE indicating an amount of UE transmit power amplifier power back off.

In one example, receiving the uplink data traffic signal is performed when the UE is in a connected Radio Resource Control (RRC) status. In one example, the power back off IE comprises an integer indicating steps of 0.5 dB.

In one example, measuring the OOB power includes measuring a first average power of the uplink beam, measuring a second average power leakage into OOB locations from the uplink beam, and determining a ratio of the first average power divided by the second average power. In another example, measuring the first average power comprises measuring an average power of resource elements carrying physical uplink shared channel (PUSCH) ports for the UE. In another example, measuring the second average power comprises measuring an average power in OOB locations and scaling the average power measured in each location based on offset from the uplink data traffic channel.

Yet another aspect provides a base station in a wireless communication network with a wireless transceiver comprising a nonlinear power amplifier, a memory, and a processor communicatively coupled to the wireless transceiver and the memory. The processor is configured to, receive an uplink data traffic signal on a physical uplink channel from a UE at the base station, measure an out of band (OOB) power of the received uplink data traffic signal, the OOB power comprising an average power of the uplink data traffic signal in one or more OOB locations of the wireless communication network, offset from the physical uplink channel, determine a power back for the UE using the measured OOB power, and send a power back off information element (IE) to the UE in a downlink control channel, the power back off IE indicating an amount of UE transmit power amplifier power back off.

In one example, receiving the uplink data traffic signal is performed when the UE is in a connected Radio Resource Control (RRC) status. In one example, measuring the OOB power comprises measuring a first average power of the uplink beam, measuring a second average power leakage into OOB locations from the uplink beam, and determining a ratio of the first average power divided by the second average power.

These and other aspects will become more fully understood upon a review of the detailed description, which follows. Other aspects, features, and embodiments will become apparent to those of ordinary skill in the art, upon reviewing the following description of specific, exemplary embodiments of in conjunction with the accompanying figures. While features may be discussed relative to certain embodiments and figures below, all embodiments can include one or more of the advantageous features discussed herein. In other words, while one or more embodiments may be discussed as having certain advantageous features, one or more of such features may also be used in accordance with the various embodiments discussed herein. In similar fashion, while exemplary embodiments may be discussed below as device, system, or method embodiments such exemplary embodiments can be implemented in various devices, systems, and methods.

### BRIEF DESCRIPTION OF THE DRAWINGS

FIG. 1 is a schematic illustration of a wireless communication system according to some aspects.

FIG. 2 is a conceptual illustration of an example of a radio access network according to some aspects.

FIG. 3 illustrates an organization of wireless resources in an air interface utilizing orthogonal frequency divisional multiplexing (OFDM).

FIG. 4 is a block diagram illustrating exemplary components of a base station or UE according to some aspects.

FIG. 5 is a diagram illustrating power spectral density for in-band (k) and OOB locations for two different signals across a frequency range within a radio access network according to some aspects.

FIG. 6 is a signaling diagram illustrating an example of sending an OOB power measurement IE to a base station according to some aspects.

FIG. 7 is a signaling diagram illustrating an example of sending a power back-off IE to a UE according to some aspects.

FIG. 8 is a block diagram illustrating an example of a hardware implementation for a UE employing a processing system according to some aspects.

FIG. 9 is a flow chart of an exemplary method for a UE to send an OOB power measurement IE according to some aspects.

FIG. 10 is a block diagram illustrating an example of a hardware implementation for a base station employing a processing system according to some aspects.

FIG. 11 is a flow chart of an exemplary method for a base station to send a power back-off IE according to some aspects.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

The utilization efficiency of an influential resource, such as radiated power, always plays a significant role in wireless system design. The power amplifier of an RF transmitter is a major consumer of power and the source of all radiated power and so power control protocols are used to minimize radiated power between nodes in wireless communication systems. Many high-power RF power amplifiers are more efficient when operating at or near maximum or peak power. At the same time many high-power RF power amplifiers contain non-linear components with a limited dynamic range that distort the transmitted signal. This is particularly true when the peak to average power ratio (PAPR) is high.

The non-linear distortions arise in-band and directly affect the link performance. For OFDM and OFDMA signals this distortion can be measured using signal to noise and interference ratios (SINR) and error vector magnitudes (EVM) among others. Nonlinear power amplifiers also cause Out-of-Band (OOB) distortions which affect other users on the network that are using these other bands. The OOB distortion is related to adjacent channel interference (ACI).

In various aspects of the present disclosure a closed loop power back-off (BO) is applied to the nonlinear power amplifier to control the level of nonlinear distortion. The closed loop power BO control adjustment allows the amplifier to be adapted to current conditions, allowing for lower power BO and therefore higher power efficiency under many circumstances.

While aspects and embodiments are described in this application by illustration to some examples, those skilled in the art will understand that additional implementations and use cases may come about in many different arrangements and scenarios. Innovations described herein may be implemented across many differing platform types, devices, systems, shapes, sizes, packaging arrangements. For example, embodiments and/or uses may come about via integrated chip embodiments and other non-module-component based devices (e.g., end-user devices, vehicles, communication devices, computing devices, industrial equipment, retail/purchasing devices, medical devices, AI-enabled devices, etc.). While some examples may or may not be specifically directed to use cases or applications, a wide assortment of applicability of described innovations may occur. Implementations may range a spectrum from chip-level or modular components to non-modular, non-chip-level implementations and further to aggregate, distributed, or OEM devices or systems incorporating one or more aspects of the described innovations. In some practical settings, devices incorporating described aspects and features may also necessarily include additional components and features for implementation and practice of claimed and described embodiments. For example, transmission and reception of wireless signals necessarily includes several components for analog and digital purposes (e.g., hardware components including antenna, RF-chains, power amplifiers, modulators, buffer, processor(s), interleaver, adders/summers, etc.). It is intended that innovations described herein may be practiced in a wide variety of devices, chip-level components, systems, distributed arrangements, end-user devices, etc. of varying sizes, shapes, and constitution.

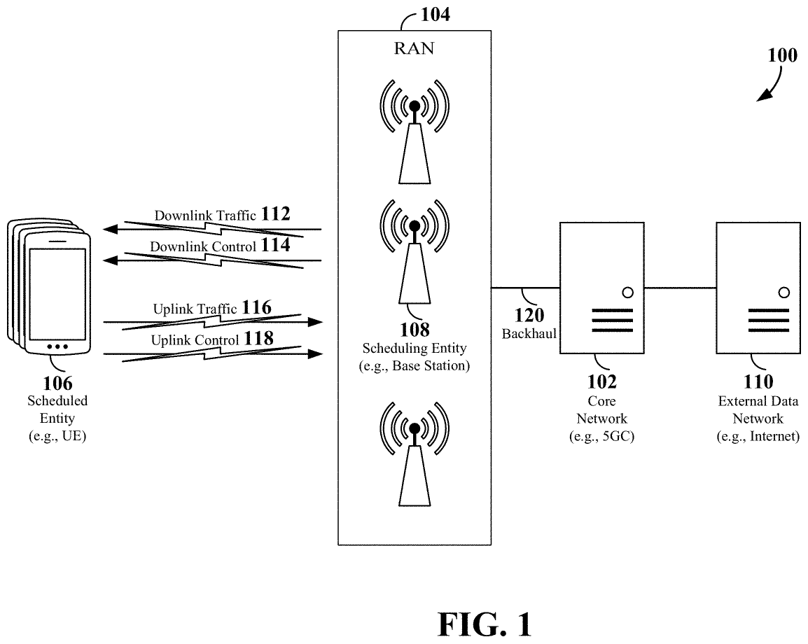

The various concepts presented throughout this disclosure may be implemented across a broad variety of telecommunication systems, network architectures, and communication standards. Referring now to FIG. 1, as an illustrative example without limitation, various aspects of the present disclosure are illustrated with reference to a wireless communication system 100. The wireless communication system 100 includes three interacting domains: a core network 102, a radio access network (RAN) 104, and a user equipment (UE) 106. By virtue of the wireless communication system 100, the UE 106 may be enabled to carry out data communication with an external data network 110, such as (but not limited to) the Internet.

The RAN 104 may implement any suitable wireless communication technology or technologies to provide radio access to the UE 106. As one example, the RAN 104 may operate according to 3rd Generation Partnership Project (3GPP) New Radio (NR) specifications, often referred to as 5G-NR. As another example, the RAN 104 may operate under a hybrid of 5G-NR and Evolved Universal Terrestrial Radio Access Network (eUTRAN) standards, often referred to as LTE. The 3GPP refers to this hybrid RAN as a next-generation RAN, or NG-RAN. Of course, many other examples may be utilized within the scope of the present disclosure.

As illustrated, the RAN 104 includes a plurality of base stations 108. Broadly, a base station is a network element in a radio access network responsible for radio transmission and reception in one or more cells to or from a UE. In different technologies, standards, or contexts, a base station may variously be referred to by those skilled in the art as a base transceiver station (BTS), a radio base station, a radio transceiver, a transceiver function, a basic service set (BSS), an extended service set (ESS), an access point (AP), a Node B (NB), an eNode B (eNB), a gNode B (gNB), or some other suitable terminology.

The radio access network 104 is further illustrated supporting wireless communication for multiple mobile apparatuses. A mobile apparatus may be referred to as user equipment (UE) in 3GPP standards, but may also be referred to by those skilled in the art as a mobile station (MS), a subscriber station, a mobile unit, a subscriber unit, a wireless unit, a remote unit, a mobile device, a wireless device, a wireless communications device, a remote device, a mobile subscriber station, an access terminal (AT), a mobile terminal, a wireless terminal, a remote terminal, a handset, a terminal, a user agent, a mobile client, a client, or some other suitable terminology. A UE may be an apparatus that provides a user with access to network services.

Within the present document, a “mobile” apparatus need not necessarily have a capability to move, and may be stationary. The term mobile apparatus or mobile device broadly refers to a diverse array of devices and technologies. UEs may include a number of hardware structural components sized, shaped, and arranged to help in communication; such components can include antennas, antenna arrays, RF chains, amplifiers, one or more processors, etc. electrically coupled to each other. For example, some non-limiting examples of a mobile apparatus include a mobile, a cellular (cell) phone, a smart phone, a session initiation protocol (SIP) phone, a laptop, a personal computer (PC), a notebook, a netbook, a smartbook, a tablet, a personal digital assistant (PDA), and a broad array of embedded systems, e.g., corresponding to an “Internet of Things” (IoT). A mobile apparatus may additionally be an automotive or other transportation vehicle, a remote sensor or actuator, a robot or robotics device, a satellite radio, a global positioning system (GPS) device, an object tracking device, a drone, a multi-copter, a quad-copter, a remote control device, a consumer and/or wearable device, such as eyewear, a wearable camera, a virtual reality device, a smart watch, a health or fitness tracker, a digital audio player (e.g., MP3 player), a camera, a game console, etc. A mobile apparatus may additionally be a digital home or smart home device such as a home audio, video, and/or multimedia device, an appliance, a vending machine, intelligent lighting, a home security system, a smart meter, etc. A mobile apparatus may additionally be a smart energy device, a security device, a solar panel or solar array, a municipal infrastructure device controlling electric power (e.g., a smart grid), lighting, water, etc.; an industrial automation and enterprise device; a logistics controller; agricultural equipment; military defense equipment, vehicles, aircraft, ships, and weaponry, etc. Still further, a mobile apparatus may provide for connected medicine or telemedicine support, i.e., health care at a distance. Telehealth devices may include telehealth monitoring devices and telehealth administration devices, whose communication may be given preferential treatment or prioritized access over other types of information, e.g., in terms of prioritized access for transport of critical service data, and/or relevant QoS for transport of critical service data.

Wireless communication between a RAN 104 and a UE 106 may be described as utilizing an air interface. Transmissions over the air interface from a base station (e.g., base station 108) to one or more UEs (e.g., UE 106) may be referred to as downlink (DL) transmission. In accordance with certain aspects of the present disclosure, the term downlink may refer to a point-to-multipoint transmission originating at a scheduling entity (described further below; e.g., base station 108). Another way to describe this scheme may be to use the term broadcast channel multiplexing. Transmissions from a UE (e.g., UE 106) to a base station (e.g., base station 108) may be referred to as uplink (UL) transmissions. In accordance with further aspects of the present disclosure, the term uplink may refer to a point-to-point transmission originating at a scheduled entity (described further below; e.g., UE 106).

In some examples, access to the air interface may be scheduled, wherein a scheduling entity (e.g., a base station 108) allocates resources for communication among some or all devices and equipment within its service area or cell. Within the present disclosure, as discussed further below, the scheduling entity may be responsible for scheduling, assigning, reconfiguring, and releasing resources for one or more scheduled entities. That is, for scheduled communication, UEs 106, which may be scheduled entities, may utilize resources allocated by the scheduling entity 108.

Base stations 108 are not the only entities that may function as scheduling entities. That is, in some examples, a UE may function as a scheduling entity, scheduling resources for one or more scheduled entities (e.g., one or more other UEs). And as discussed more below, UEs may communicate directly with other UEs in peer-to-peer fashion and/or in relay configuration.

As illustrated in FIG. 1, a scheduling entity 108 may broadcast downlink traffic 112 to one or more scheduled entities 106. Broadly, the scheduling entity 108 is a node or device responsible for scheduling traffic in a wireless communication network, including the downlink traffic 112 and, in some examples, uplink traffic 116 from one or more scheduled entities 106 to the scheduling entity 108. On the other hand, the scheduled entity 106 is a node or device that receives downlink control information 114, including but not limited to scheduling information (e.g., a grant), synchronization or timing information, or other control information from another entity in the wireless communication network such as the scheduling entity 108.

In addition, the uplink and/or downlink control information and/or traffic information may be time-divided into frames, subframes, slots, and/or symbols. As used herein, a symbol may refer to a unit of time that, in an orthogonal frequency division multiplexed (OFDM) waveform, carries one resource element (RE) per sub-carrier. A slot may carry 7 or 14 OFDM symbols. A subframe may refer to a duration of 1 ms. Multiple subframes or slots may be grouped together to form a single frame or radio frame. Of course, these definitions are not required, and any suitable scheme for organizing waveforms may be utilized, and various time divisions of the waveform may have any suitable duration.

In general, base stations 108 may include a backhaul interface for communication with a backhaul portion 120 of the wireless communication system. The backhaul 120 may provide a link between a base station 108 and the core network 102. Further, in some examples, a backhaul network may provide interconnection between the respective base stations 108. Various types of backhaul interfaces may be employed, such as a direct physical connection, a virtual network, or the like using any suitable transport network.

The core network 102 may be a part of the wireless communication system 100, and may be independent of the radio access technology used in the RAN 104. In some examples, the core network 102 may be configured according to 5G standards (e.g., 5GC). In other examples, the core network 102 may be configured according to a 4G evolved packet core (EPC), or any other suitable standard or configuration.

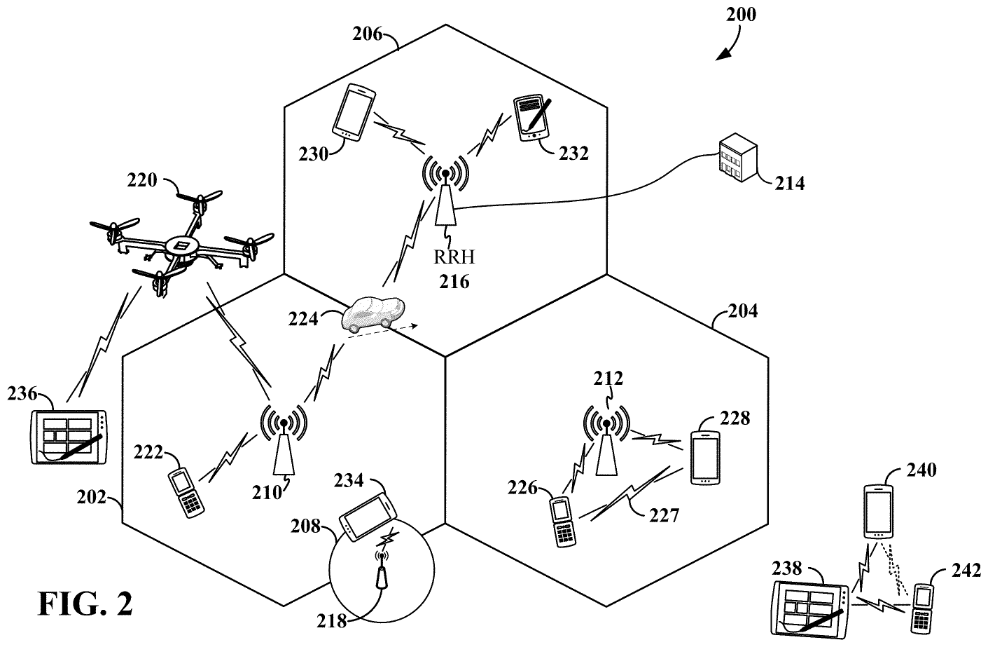

Referring now to FIG. 2, by way of example and without limitation, a schematic illustration of a RAN 200 is provided. In some examples, the RAN 200 may be the same as the RAN 104 described above and illustrated in FIG. 1. The geographic area covered by the RAN 200 may be divided into cellular regions (cells) that can be uniquely identified by a user equipment (UE) based on an identification broadcasted from one access point or base station. FIG. 2 illustrates macrocells 202, 204, and 206, and a small cell 208, each of which may include one or more sectors (not shown). A sector is a sub-area of a cell. All sectors within one cell are served by the same base station. A radio link within a sector can be identified by a single logical identification belonging to that sector. In a cell that is divided into sectors, the multiple sectors within a cell can be formed by groups of antennas with each antenna responsible for communication with UEs in a portion of the cell.

Various base station arrangements can be utilized. For example, in FIG. 2, two base stations 210 and 212 are shown in cells 202 and 204; and a third base station 214 is shown controlling a remote radio head (RRH) 216 in cell 206. That is, a base station can have an integrated antenna or can be connected to an antenna or RRH by feeder cables. In the illustrated example, the cells 202, 204, and 126 may be referred to as macrocells, as the base stations 210, 212, and 214 support cells having a large size. Further, a base station 218 is shown in the small cell 208 (e.g., a microcell, picocell, femtocell, home base station, home Node B, home eNode B, etc.) which may overlap with one or more macrocells. In this example, the cell 208 may be referred to as a small cell, as the base station 218 supports a cell having a relatively small size. Cell sizing can be done according to system design as well as component constraints.

It is to be understood that the radio access network 200 may include any number of wireless base stations and cells. Further, a relay node may be deployed to extend the size or coverage area of a given cell. The base stations 210, 212, 214, 218 provide wireless access points to a core network for any number of mobile apparatuses. In some examples, the base stations 210, 212, 214, and/or 218 may be the same as the base station/scheduling entity 108 described above and illustrated in FIG. 1.

Within the RAN 200, the cells may include UEs that may be in communication with one or more sectors of each cell. Further, each base station 210, 212, 214, and 218 may be configured to provide an access point to a core network 102 (see FIG. 1) for all the UEs in the respective cells. For example, UEs 222 and 224 may be in communication with base station 210; UEs 226 and 228 may be in communication with base station 212; UEs 230 and 232 may be in communication with base station 214 by way of RRH 216; and UE 234 may be in communication with base station 218. In some examples, the UEs 222, 224, 226, 228, 230, 232, 234, 238, 240, and/or 242 may be the same as the UE/scheduled entity 106 described above and illustrated in FIG. 1.

In some examples, an unmanned aerial vehicle (UAV) 220, which may be a drone or quadcopter, can be a mobile network node and may be configured to function as a UE. For example, the UAV 220 may operate within cell 202 by communicating with base station 210.

In a further aspect of the RAN 200, sidelink signals may be used between UEs without necessarily relying on scheduling or control information from a base station. For example, two or more UEs (e.g., UEs 226 and 228) may communicate with each other using peer to peer (P2P) or sidelink signals 227 without relaying that communication through a base station (e.g., base station 212). In a further example, UE 238 is illustrated communicating with UEs 240 and 242. Here, the UE 238 may function as a scheduling entity or a primary sidelink device, and UEs 240 and 242 may each function as a scheduled entity or a non-primary (e.g., secondary) sidelink device. In still another example, a UE may function as a scheduling entity or scheduled entity in a device-to-device (D2D), peer-to-peer (P2P), vehicle-to-vehicle (V2V) network, vehicle-to-everything (V2X) and/or in a mesh network. In a mesh network example, UEs 240 and 242 may optionally communicate directly with one another in addition to communicating with the scheduling entity 238. Thus, in a wireless communication system with scheduled access to time-frequency resources and having a cellular configuration, a P2P configuration, or a mesh configuration, a scheduling entity and one or more scheduled entities may communicate utilizing the scheduled resources. In some examples, the sidelink signals 227 include sidelink traffic and sidelink control.

The air interface in the radio access network 200 may utilize one or more multiplexing and multiple access algorithms to enable simultaneous communication of the various devices. For example, 5G NR specifications provide multiple access for UL transmissions from UEs 222 and 224 to base station 210, and for multiplexing for DL transmissions from base station 210 to one or more UEs 222 and 224, utilizing orthogonal frequency division multiplexing (OFDM) with a cyclic prefix (CP). In addition, for UL transmissions, 5G NR specifications provide support for discrete Fourier transform-spread-OFDM (DFT-s-OFDM) with a CP (also referred to as single-carrier FDMA (SC-FDMA)). However, within the scope of the present disclosure, multiplexing and multiple access are not limited to the above schemes, and may be provided utilizing time division multiple access (TDMA), code division multiple access (CDMA), frequency division multiple access (FDMA), sparse code multiple access (SCMA), resource spread multiple access (RSMA), or other suitable multiple access schemes. Further, multiplexing DL transmissions from the base station 210 to UEs 222 and 224 may be provided utilizing time division multiplexing (TDM), code division multiplexing (CDM), frequency division multiplexing (FDM), orthogonal frequency division multiplexing (OFDM), sparse code multiplexing (SCM), or other suitable multiplexing schemes.

The air interface in the radio access network 200 may further utilize one or more duplexing algorithms. Duplex refers to a point-to-point communication link where both endpoints can communicate with one another in both directions. Full duplex means both endpoints can simultaneously communicate with one another. Half duplex means only one endpoint can send information to the other at a time. In a wireless link, a full duplex channel generally relies on physical isolation of a transmitter and receiver, and suitable interference cancellation technologies. Full duplex emulation is frequently implemented for wireless links by utilizing frequency division duplex (FDD) or time division duplex (TDD). In FDD, transmissions in different directions operate at different carrier frequencies. In TDD, transmissions in different directions on a given channel are separated from one another using time division multiplexing. That is, at some times the channel is dedicated for transmissions in one direction, while at other times the channel is dedicated for transmissions in the other direction, where the direction may change very rapidly, e.g., several times per slot.

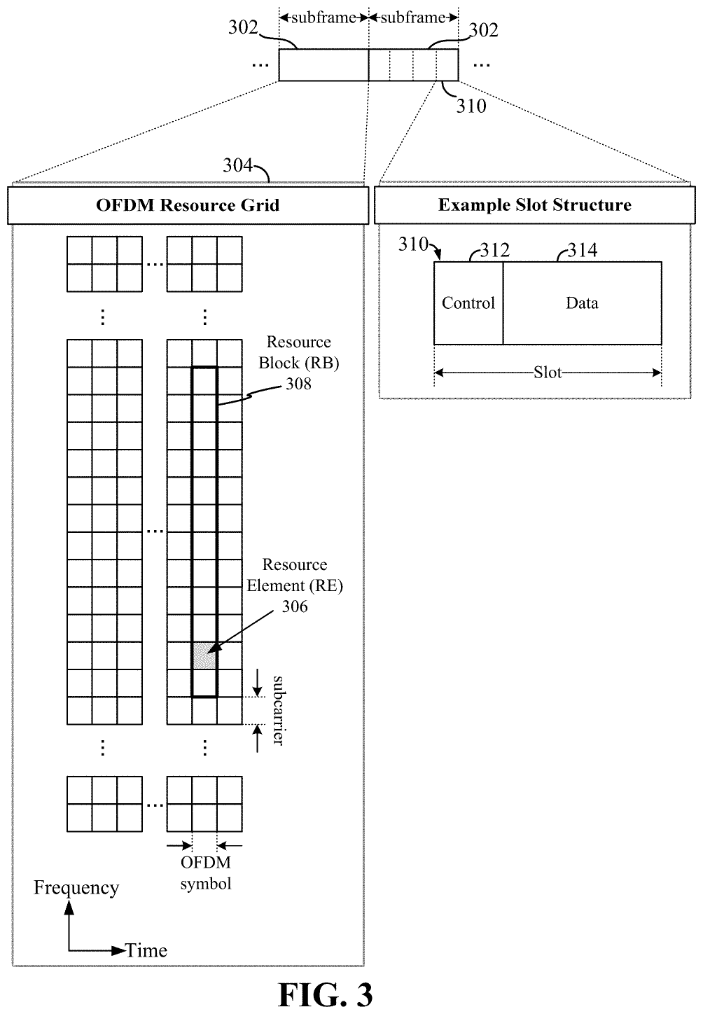

Various aspects of the present disclosure will be described with reference to an OFDM waveform, schematically illustrated in FIG. 3. It should be understood by those of ordinary skill in the art that the various aspects of the present disclosure may be applied to a DFT-s-OFDMA waveform in substantially the same way as described herein below. That is, while some examples of the present disclosure may focus on an OFDM link for clarity, it should be understood that the same principles may be applied as well to DFT-s-OFDMA waveforms.

As referred to within the present disclosure, a frame may refer to a duration of 10 ms for wireless transmissions, with each frame consisting of 10 subframes of 1 ms each. On a given carrier, there may be one set of frames in the UL, and another set of frames in the DL. Referring now to FIG. 3, an expanded view of an example downlink subframe 302 is illustrated, showing an OFDM resource grid 304. However, as those skilled in the art will readily appreciate, the PHY transmission structure for any particular application may vary from the example described here, depending on any number of factors. Here, time is in the horizontal direction with units of OFDM symbols; and frequency is in the vertical direction with units of subcarriers or tones.

The resource grid 304 may be used to schematically represent time-frequency resources for a given antenna port. That is, in a MIMO implementation with multiple antenna ports available, a corresponding multiple number of resource grids 304 may be available for communication. The resource grid 304 is divided into multiple resource elements (REs) 306. An RE, which is 1 subcarrier×1 symbol, is the smallest discrete part of the time-frequency grid, and contains a single complex value representing data from a physical channel or signal. Depending on the modulation utilized in a particular implementation, each RE may represent one or more bits of information. In some examples, a block of REs may be referred to as a physical resource block (PRB) or more simply a resource block (RB) 308, which contains any suitable number of consecutive subcarriers in the frequency domain. In one example, an RB may include 12 subcarriers, a number independent of the numerology used. In some examples, depending on the numerology, an RB may include any suitable number of consecutive OFDM symbols in the time domain. Within the present disclosure, it is assumed that a single RB such as the RB 308 entirely corresponds to a single direction of communication (either transmission or reception for a given device).

A UE generally utilizes only a subset of the resource grid 304. An RB may be the smallest unit of resources that can be allocated to a UE. Thus, the more RBs scheduled for a UE, and the higher the modulation scheme chosen for the air interface, the higher the data rate for the UE. In this illustration, the RB 308 is shown as occupying less than the entire bandwidth of the subframe 302, with some subcarriers illustrated above and below the RB 308. In a given implementation, the subframe 302 may have a bandwidth corresponding to any number of one or more RBs 308. Further, in this illustration, the RB 308 is shown as occupying less than the entire duration of the subframe 302, although this is merely one possible example.

Each 1 millisecond (ms) subframe 302 may consist of one or multiple adjacent slots. In the example shown in FIG. 3, one subframe 302 includes four slots 310, as an illustrative example. In some examples, a slot may be defined according to a specified number of OFDM symbols with a given cyclic prefix (CP) length. For example, a slot may include 7 or 14 OFDM symbols with a nominal CP. Additional examples may include mini-slots having a shorter duration (e.g., one or two OFDM symbols). These mini-slots may in some cases be transmitted occupying resources scheduled for ongoing slot transmissions for the same or for different UEs.

An expanded view of one of the slots 310 illustrates the slot 310 including a control region 312 and a data region 314. In general, the control region 312 may carry control channels (e.g., the PDCCH), and the data region 314 may carry data channels (e.g., PDCCH or PUSCH). Of course, a slot may contain all DL, all UL, or at least one DL portion and at least one UL portion. The structure illustrated in FIG. 3 is merely examplary in nature, and different slot structures may be utilized, and may include one or more of each of the control region(s) and data region(s).

Although not illustrated in FIG. 3, the various REs 306 within an RB 308 may be scheduled to carry one or more physical channels, including control channels, shared channels, data channels, etc. Other REs 306 within the RB 308 may also carry pilots or reference signals, including but not limited to a demodulation reference signal (DMRS) a control reference signal (CRS), or a sounding reference signal (SRS). These pilots or reference signals may provide for a receiving device to perform channel estimation of the corresponding channel, which may enable coherent demodulation/detection of the control or data channels within the RB 308.

In a DL transmission, the transmitting device (e.g., the scheduling entity 108) may allocate one or more REs 306 (e.g., within a control region 312) to carry DL control information 114 including one or more DL control channels, such as a PBCH; a PSS; a SSS; a physical control format indicator channel (PCFICH); a physical hybrid automatic repeat request (HARQ) indicator channel (PHICH); or a physical downlink control channel (PDCCH), etc., to one or more scheduled entities 106. The PCFICH provides information to assist a receiving device in receiving and decoding the PDCCH. The PDCCH carries downlink control information (DCI) including but not limited to power control commands, scheduling information, a grant, or an assignment of REs for DL and UL transmissions. The PHICH carries HARQ feedback transmissions such as an acknowledgment (ACK) or negative-acknowledgment (NACK). HARQ is a technique well-known to those of ordinary skill in the art, wherein the integrity of packet transmissions may be checked at the receiving side for accuracy, e.g., utilizing any suitable integrity checking mechanism, such as a checksum or a cyclic redundancy check (CRC). If the integrity of the transmission confirmed, an ACK may be transmitted, whereas if not confirmed, a NACK may be transmitted. In response to a NACK, the transmitting device may transmit a HARQ retransmission, which may implement chase combining, incremental redundancy, etc.

In an UL transmission, the transmitting device (e.g., the scheduled entity 106) may utilize one or more REs 306 to carry UL control information 118 including one or more UL control channels, such as a physical uplink control channel (PUCCH), to the scheduling entity 108. UL control information may include a variety of packet types and categories, including pilots, reference signals, and information configured to enable or assist in decoding uplink data transmissions. In some examples, the control information 118 may include a scheduling request (SR), e.g., a request for the scheduling entity 108 to schedule uplink transmissions. Here, in response to the SR transmitted on the control channel 118, the scheduling entity 108 may transmit downlink control information 114 that may schedule resources for uplink packet transmissions. UL control information may also include HARQ feedback, channel state feedback (CSF), or any other suitable UL control information.

In addition to control information, one or more REs 306 (e.g., within the data region 314) may be allocated for user data or traffic data. Such traffic may be carried on one or more traffic channels, such as, for a DL transmission, a physical downlink shared channel (PDSCH); or for an UL transmission, a physical uplink shared channel (PUSCH). In some examples, one or more REs 306 within the data region 314 may be configured to carry system information blocks (SIB s), carrying information that may enable access to a given cell.

The channels or carriers described above and illustrated in FIGS. 1-3 are not necessarily all the channels or carriers that may be utilized between a scheduling entity 108 and scheduled entities 106, and those of ordinary skill in the art will recognize that other channels or carriers may be utilized in addition to those illustrated, such as other traffic, control, and feedback channels.

These physical channels described above are generally multiplexed and mapped to transport channels for handling at the medium access control (MAC) layer. Transport channels carry blocks of information called transport blocks (TB). The transport block size (TBS), which may correspond to a number of bits of information, may be a controlled parameter, based on the modulation and coding scheme (MCS) and the number of RBs in a given transmission.

In a 5G network, a base station may configure UEs to periodically perform measurements of a beam for beam management or radio link monitoring, among other examples, and to periodically provide feedback reports carrying the measurements, or metrics or other information obtained based on the measurements, to the base station. For example, the base station may periodically transmit a channel station information (CSI) reference signal (CSI-RS) and a UE may perform measurements on the CSI-RS to provide CSI to the base station via CSI reports. The CSI may include, for example, channel quality information (CQI) and a reference signal received power (RSRP) for the beam. The serving base station or radio access network (RAN) may control the frequency with which the UE provides such feedback reports. However, the frequency with which such feedback reports are scheduled by the base station may be inadequate to maintain sufficient beam quality or reliability in scenarios in which channel conditions are changing rapidly. For instance, when a UE is in motion, obstacles or various environmental conditions may cause reception of a directional beam to quickly degrade.

According to various aspects, a UE may unilaterally initiate a request to the serving base station to change or enhance beam coverage at the UE. In some aspects, the UE may measure one or more characteristics of a directional beam transmitted by a base station and ascertain whether channel reliability for the beam should be improved. The UE may determine channel reliability by taking one or more measurements of the beam and determine whether such measurements are above a minimum desired threshold. In some examples, if the UE determines that the channel reliability is below a threshold, the UE may transmit a request to the base station seeking to adjust the coverage of the beam (e.g. seeking coverage enhancements). For example, such a request may seek to adjust one or more transmit or receive parameters associated with the beam or channels transmitted therein. In one instance, the UE may switch to using a pre-defined set of coverage enhancement parameters or procedures either automatically after transmitting the request or upon receipt of a grant by the base station.

Examples of coverage enhancement parameters may include (but are not limited to) a repetition parameter, a time resource allocation parameter, a frequency resource allocation parameter, a payload size parameter, or other types of parameters associated with a received beam or channel(s) therein. The repetition parameter may indicate a quantity of repetitions for transmitting or receiving a particular type of communication, such as a reference signal (RS), a report, a PDCCH communication, a PDSCH communication, a PUCCH communication, a PUSCH communication, or the like. The time resource allocation parameter may indicate one or more time domain resources (e.g., slots, symbols, subframes, or the like) for transmitting or receiving a particular type of communication, such as a reference signal, a report, a PDCCH communication, a PDSCH communication, a PUCCH communication, a PUSCH communication, or the like. The frequency resource allocation parameter may indicate one or more frequency domain resources (e.g., resource blocks (RBs), resource elements (REs), subcarriers, component carriers, or the like) for transmitting or receiving a particular type of communication, such as a reference signal, a report, a PDCCH communication, a PDSCH communication, a PUCCH communication, a PUSCH communication, or the like. The payload size parameter may indicate a payload size limit for a particular type of communication, such as a reference signal, a report, a PDCCH communication, a PDSCH communication, a PUCCH communication, a PUSCH communication, or the like.

An example of coverage enhancement procedures may include increasing multi-path signal reception or processing at the UE. By increasing multi-path signal reception (e.g., increase resources to capture more multi-path signals), the UE can seek to improve reliability of the beam or channels therein. Such coverage enhancements at the UE may automatically terminate after a predefined period of time, or upon receipt of a beam switch command from the base station.

These physical channels described above are generally multiplexed and mapped to transport channels for handling at the medium access control (MAC) layer. Transport channels carry blocks of information called transport blocks (TB). The transport block size (TBS), which may correspond to a number of bits of information, may be a controlled parameter, based on the modulation and coding scheme (MCS) and the number of RBs in a given transmission.

The channels or carriers described above in connection with FIGS. 1-3 are not necessarily all of the channels or carriers that may be utilized between a scheduling entity and scheduled entities, and those of ordinary skill in the art will recognize that other channels or carriers may be utilized in addition to those illustrated, such as other traffic, control, and feedback channels.

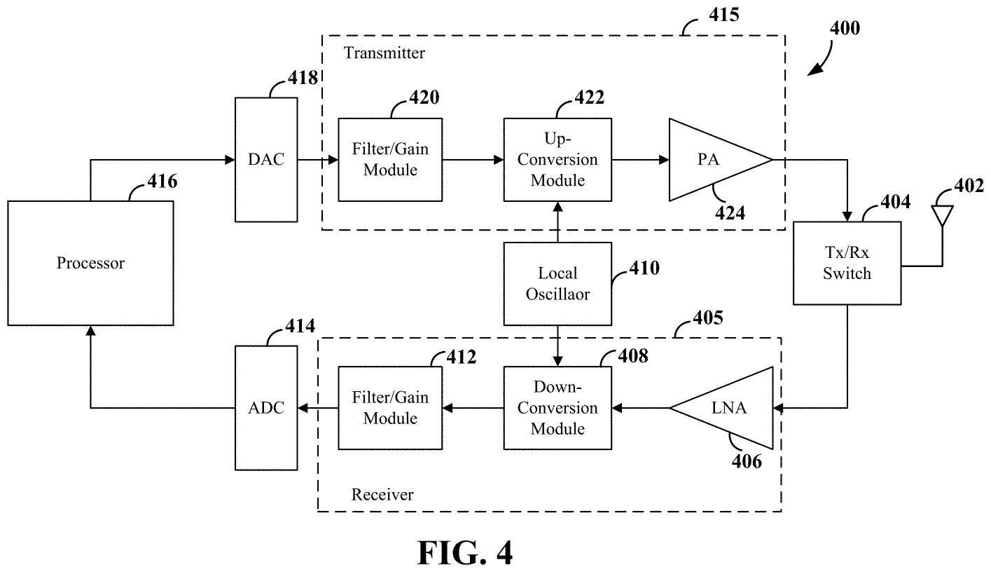

FIG. 4 illustrates an example of a UE 400 configured with a shared (e.g., common) LO 410 for both downlink and uplink transmissions. The UE 400 includes an antenna 402, a Tx/Rx switch module 404, a receiver 405, a transmitter 415, the LO 410, an analog-to-digital (ADC) converter 414, a digital-to-analog (DAC) converter 418, and a processor 416. The receiver 405 includes a low noise amplifier (LNA) 406, a down-conversion module 408, and a receiving filter/gain module 412. The transmitter 415 includes a transmitting filter/gain module 420, an up-conversion module 422, and a power amplifier (PA) 424.

The antenna 402 is shared by the transmitter 415 and receiver 405, as regulated by the TX/RX switch module 404. The antenna 402 may be a single antenna that is shared by transmit and receive paths (half-duplex) or may include separate antennas for the transmit path and receive path (full-duplex). The antenna 402 may further include multiple transmit and/or receive antennas to support MIMO and/or beamforming technology. In this example, the PA 424 may include multiple PA elements, and the LNA 406 may include multiple LNA elements. In addition, other components of the UE 400 may include multiple elements to support simultaneous transmission or reception of multiple signals (e.g., MIMO signals).

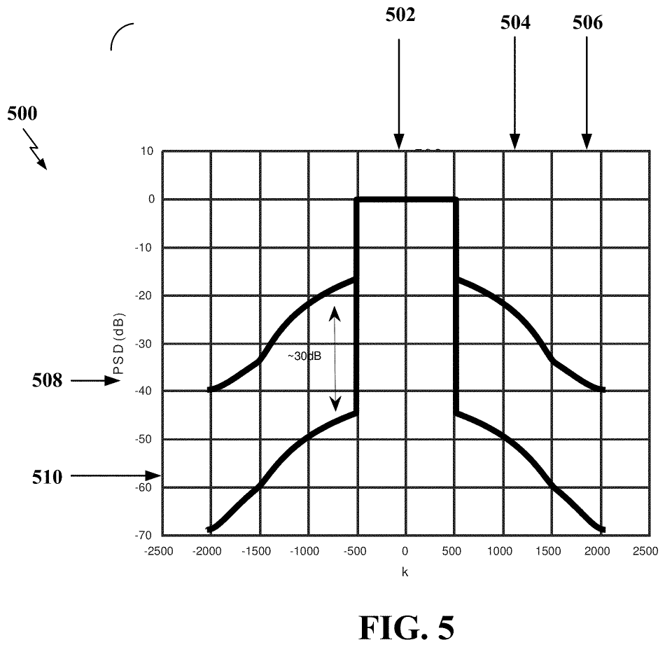

The LNA 406 is configured to receive an inbound radio frequency (RF) signal transmitted, for example, by a base station from the antenna 402 via the Tx/Rx switch module 404. The LNA 406 is further configured to amplify the RF signal to produce an amplified RF signal. The down-conversion module 408 is configured to receive the amplified RF signal from the LNA 406 and to convert the amplified RF signal into a low intermediate frequency (IF) signal or baseband signal based on a local oscillation provided by the LO 410. The receiving filter/gain module 412 is configured to receive the low IF or baseband signal from the down-conversion module and to filter and/or adjust the gain of the low IF or baseband signal before providing the low IF or baseband signal to the ADC 414. The ADC 414 converts the low IF or baseband signal from the analog domain to the digital domain to produce a digital signal that may be processed by the processor 416. For example, the processor 416 may demodulate, demap, descramble, and/or decode the digital signal to produce an original bit stream corresponding to control information and/or user data traffic. In some examples, the processor 416 may include digital receiver processing module 542 shown in FIG. 5.

The processor 416 may further process an original bit stream corresponding to control information and/or user data traffic. For example, the processor 416 may modulate, map, scramble, and code the original bit stream to produce a digital baseband signal. In some examples, the processor 416 may include the digital transmitter processing module 540 shown in FIG. 5. The digital baseband or low IF signal may be input to the DAC 418 for conversion of the digital baseband or low IF signal from the digital domain to the analog domain to produce an analog baseband or low IF signal. The transmitting filter/gain module 420 is configured to receive the analog baseband or low IF signal and to filter and/or adjust the gain of the analog baseband or low IF signal before providing the analog baseband or low IF signal to the up-conversion module 422. The up-conversion module 422 converts the analog baseband signal, or low IF signal, into an RF signal based on a transmitter local oscillation provided by the LO 410. The PA 424 amplifies the RF signal to produce an outbound RF signal for transmission to, for example, a base station, via the Tx/Rx switch module 404 and the antenna 402.

In some examples, the inbound RF signal and/or outbound RF signal may include a mmWave signal. In addition, the inbound RF signal and/or outbound RF signal may include one or more component carriers within a mmWave bandwidth (e.g., a wideband). For example, the inbound RF signal may include multiple (e.g., two or more) component carriers of the mmWave bandwidth, whereas the outbound RF signal may include at least one component carrier of the mmWave bandwidth. In some examples, a single component carrier may be sufficient for uplink use cases. In 5G NR mmWave may also be referred to as Frequency Range 2 (FR2) and include carriers from about 24 GHz-53 GHz, although this may be expanded or changed over time. The systems described herein may also be applied to other carriers including sub-6, i.e. frequencies below 6 GHz also referred to as Frequency Range 1 (FR1).

The larger bandwidth and beamforming (with multiple antenna elements, PA elements, and LNA elements) involved when the UE 400 is operating in an intra-band carrier aggregation mode associated with a wideband mmWave bandwidth may increase the power consumption of the UE 400 in the analog domain. In addition, with a higher bandwidth and carrier aggregation, the sampling rate of the ADC 414/DAC 418 may be increased and digital blocks of the DFE (e.g., within the processor 416) may need to be clocked at a higher rate, thus further increasing the total power consumption of the UE 400.

Therefore, in various aspects of the disclosure, the UE 400 may be configured to select an uplink component carrier within the wideband mmWave bandwidth to optimize or reduce power consumption in the UE 400. In some examples, the UE 400 may select an uplink component carrier that is centered around or otherwise includes the center frequency of the shared LO 410. In other examples, the UE 400 may select an uplink component carrier that is as close as possible to the center frequency of the LO 410. By selecting an uplink component carrier near the LO center frequency, the instantaneous bandwidth (IBW) on the uplink may be reduced, thus reducing the sampling rate and clock rate in the DFE of the processor 416. While FIG. 4 is described in the context of a UE a base station may have a similar structure with a similar transmitter 415.

The utilization efficiency of an influential resource, such as radiated power, always plays a significant role in wireless system design. The power amplifier of an RF transmitter is a major consumer of power and the source of all radiated power and so power control protocols are used to minimize radiated power between nodes in wireless communication systems. Many high-power RF power amplifiers, such as PA 424, among others, are more efficient when operating at or near maximum or peak power. At the same time many high-power RF power amplifiers contain non-linear components with a limited dynamic range that distort the transmitted signal. This is particularly true when the peak to average power ratio (PAPR) is high.

The non-linear distortions arise in-band and directly affect the link performance. For OFDM and OFDMA signals this distortion can be measured using signal to noise and interference ratios (SINR) and error vector magnitudes (EVM) among others. Nonlinear power amplifiers also cause Out-of-Band (OOB) distortions which affect other users on the network that are using these other bands. The OOB distortion is related to adjacent channel interference (ACI). The ACI indicates how much the adjacent channel is “polluted” by the distorted transmission.

As described herein, a closed loop power back-off (BO) is applied to the nonlinear power amplifier to control the level of nonlinear distortion. The closed loop power BO control adjustment allows the amplifier to be adapted to current conditions, allowing for lower power BO and therefore higher power efficiency under many circumstances.

FIG. 5 is a diagram illustrating power spectral density on the vertical axis for in-band (k) and OOB locations for two different signals across a frequency range on the horizontal axis. k represents a center frequency of an in-band signal 502. As an example, in frequency range 2 (FR2) or Sub-6 communications for a carrier below 6 GHz as described for 5G NR, the transmitters are required to maintain an ACI/ACLR (Adjacent Channel Leakage Power Ratio) of about 45 dB. The FR2 signal 510 is represented by the main in band signal 502 and the side bands extending laterally from the central channel starting at about −45 dB and extending laterally and downward as the OOB distortion diminishes with distance from the center frequency. In use, equipment may be set to 47-49 dB to ensure that the standard of −45 dB is not exceeded.

Similarly, in frequency range 1 (FR1) or mmWave communications, the transmitters are required to maintain an ACI/ACLR of about 15 dB because signals at these frequencies are less sensitive to OOB distortion. The FR1 signal 508 is superimposed over the FR2 signal 510 and also centered at k with the same in band signal 502. The side bands of the FR1 signal 508 start at about 15 dB and also extend laterally and downward with distance from the in-band signal. While the FR2 requirement is 30 db less than that of the FR1 requirement as shown, the 15 dB requirement is also significant. In use 17-19 dB is maintained by most equipment. As described herein the power spectral density of another measure of the signal power may be taken in band at k and OOB at multiple different locations 504, 506 that are offset from the center frequency k. Measurements at multiple locations 504, 506 provide information about how quickly the signals diminish as the offset increases. In this example, the measurements are taken at about ±1200 and ±1800 as indicated in the diagram but other offset locations may be used to suit different types of radio, and communication network systems.

Equipment manufacturers meet these ACI/ACLR standards by calibrating the equipment before use. This is an open loop configuration in that the equipment does not respond to circumstances in the field, such as changes in the radio network environment, changes in the operational conditions of the equipment and degradation due to age and other physical factors. Just as the equipment is designed not to overheat in the most extreme conditions, the equipment is designed not to exceed the ACI/ACLR standards in the most extreme conditions. This overdesign means that the ACI/ACLR is often much lower than necessary. In many conditions the PA power may be 6-10 dB lower than necessary and the link budget is significantly reduced.

As described herein, the nonlinear distortion may be controlled at least in part by changing the power BO in a closed loop control technique. The nonlinear emissions are measured directly or indirectly and then the power BO is adjusted using the control loop to maintain a distortion level that the network can tolerate. In examples, the network measures the ACI, ACLR, and perhaps also the in-band EVM or any other suitable representation of the distortion caused by the transmitter. The network can then decide for each link how much power BO to apply to each side of the link. Since the distortions may be different for different links even with the same base station, each link may be controlled separately.

Using distortion measurements of UL and DL signals, the network determines a power BO for each direction. The network may control the UE by sending a message that includes adjustment of its power BO in real time. The network can also adjust its own power BO based on measurements received from the UE. The power BO message may be sent as differential or absolute values regarding the PA power or the PA BO. In some embodiments, the power BO is differential to indicate that that power BO should be increased or decreased by one or more steps. The amount of BO may be iterated up and down until a satisfactory level of OOB interference is reached. Since the communications environment and the UE equipment are not changing rapidly, the total overhead for the power BO control messages and measurement messages is not great.

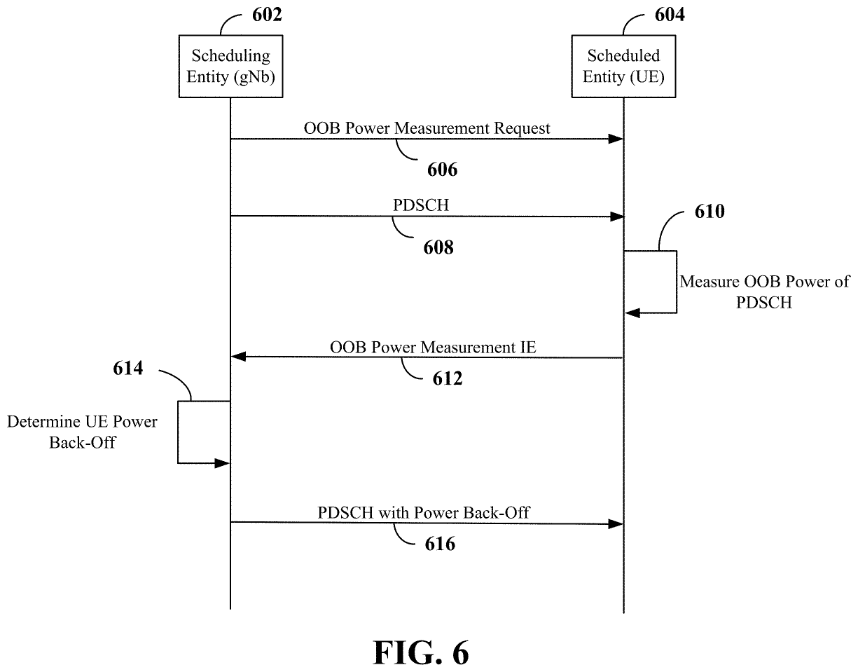

FIG. 6 is a signaling diagram illustrating an example of a scheduled entity or UE reporting an OOB power measurement to a scheduling entity or gNb. The scheduling entity 602 (e.g., base station or gNb) is in wireless communication with a scheduled entity 604 (e.g., a UE). The scheduling entity 602 may correspond to any of the scheduling entities or base stations shown in FIGS. 1, 2, and 4 that includes a nonlinear RF power amplifier for transmission to the UE. The scheduled entity 604 may correspond to any of the scheduled entities or UEs shown in FIGS. 1, 2, and 4.

At signal 606, the base station optionally transmits an OOB interference measurement request to the UE. The request may be transmitted when a measurement is desired or periodically. In some embodiments, this signal may use a reportType message with a gNb trigger that is periodical or aperiodical. Accordingly, the UE may make measurements in response to trigger events or triggered by a periodic schedule. The base station may send this signal separate and apart from any traffic data signal such as using Layer 3 (L3) filtering requirements. A downlink control channel signal, e.g. PDCCH, may be used.

At signal 608, the base station transmits a data traffic signal to the UE, such as a PDSCH. Such signals are particularly suitable for an RRC (Radio Resource Control) status of RRC_CONNECTED. Currently, RRC also has idle and inactive states during which no data traffic is exchanged. At operation 610, the UE makes measurements of the OOB power due to the PDSCH. By its nature, a measurement of a signal received by the UE is a measure not just of the nonlinearity of the transmit power amplifier but to the entire transmitter or transmit chain. An important part of the signal distortion from the transmitter is reflected in the signal power that leaks or is injected into OOB channels. There are many different signal power, distortion, and noise measurements. In 5G NR many of these are defined in the Protocol Specification Section 38.215: 5, Measurement Capabilities for NR, which includes received power, received quality, signal-to-noise and interference ratio. (SINR), and adjacent channel leakage ratio (ACLR). ACLR is a ratio of the transmitted power to the power in an adjacent radio channel.

An additional measurement may be defined in the Protocol Specification Section 38.215:5 or in some other location, specifically for OOB interference, such as an ACLR measurement. In some embodiments, the ACLR may be defined as the relative power (in dB), between the average power of the resource elements carrying PDSCH (e.g. ports 1000-1007) signals divided by the average power of the PDSCH leakage into other OOB locations. As a further refinement, the OOB locations may be allocated as a contribution to the average power in units of % of the allocated bandwidth. The allocations may take different values such as (−70% −50% −20%, +20%, +50%, +70%). This approach measures the power at three different frequencies on either side of the center frequency of a resource element. The number of elements may be modified to suit different implementations and the measurement may be asymmetrical or stepped, such as (−70%, −20%, +50%) or any other suitable pattern.

In some examples, the average power may be determined with respect to some predefined frequency width, and predefined timing window. The predefined window may be a multiple number of slots of allocated to in-band data in the time domain. The average power may be measured using the same or similar frequency and time dimensions for the in-band channel and out of-band-channels. More specifically, a center frequency of the allocated physical downlink channel may be determined. An edge may also be determined based on the center frequency and the allocated bandwidth, such as X MHz. The in-band average power may be measured within a predefined frequency width that is a selected distance on both sides of the center frequency during a predefined timing window. The predefined frequency width is selected as less than the allocated bandwidth so that edge effects within the bandwidth are not measured. The predefined timing window is a measurement interval of a same or similar number, Z, of slots of allocated data in the time domain.

The out-of-band average power may be measured across bandwidths that are centered about the set of out-of-band frequency locations. The distance from the physical downlink channel may be measured from the edge frequency of the allocated bandwidth, X MHz, or from the center frequency of the physical downlink channel allocation. In one example, the center of each out-of-band location is taken as a distance, ±Y1, ±Y2, ±Y3 MHz, from the edge X MHz of the in-band allocation. Y1 is a first percentage, such as 20%, of the in-band bandwidth allocation. In the example of FIG. 5, the bandwidth allocation is 1 MHz so that Y1 would be 0.2 MHz. Y2 is a second percentage, such as 50%, of the bandwidth allocation or 0.5 MHz, and Y3 is a third percentage, such as 70% or 0.7 MHz, of the bandwidth allocation. While 20%, 50%, and 70% have been tested to provide useful results under the tested environments, more or fewer locations and different percentages may be used to suit different conditions.

Using Y1, in the context of FIG. 5, the edges of the bandwidth allocation are given as +500 MHz and −500 MHz from the center frequency which is indicated as 0. The first or Y1 location is at +20 MHz and −20 MHz from the respective edges of the bandwidth allocation or +520 MHz and −520 MHz. The average power measurement at these frequencies may be made with the same or similar frequency width and timing window as the in-band average power measurement. The Y2 and Y3 average power measurements may be made similarly. The positions of the Y2 and Y3 measurements may be made in the same way as for Y1 to give (20/50/70) percent measurements. The measurements may be made for a measurement interval of a same or similar number, Z, of slots of allocated data in the time domain The PAPR measurement is defined as the ratio of the measured average in-band power to the measured out-of-band power. The average power at each location may be scaled before taking the ratio.

In this example, the UE measures the power at each of the, e.g. 6, offsets and compares the measured power to the in-band power to obtain a ratio. As an example, the average in band power for the respective resource element may then be separately divided by the respective measurement at each of the six offset locations. The comparison may be a division or a scaling to show each OOB power relative to the in-band power. The measurements may then be scaled or divided to provide a simple indication of the ACLR such as a 4-bit, 5-bit or 8-bit value for each location. Alternatively, the measurements may be combined to provide a single representation of the total ACLR. Alternatively, ACLR as defined in the Technical Specification may be used or the ACI/ACLR may be used. The measurements may then be combined to generate an information element (IE). One or more IEs may be used to convey the measurement information back to the base station.

At signal 612, the UE sends an IE that indicates the measured power to the base station. The measurement is made useful by a report back to the base station. The measurement is accordingly sent from the UE to the base station. There are many different possible ways to send back the measurement. In some embodiments, an information element is generated and added to an existing packet. One such suitable packet is defined in the 5G NR Radio Resource Control Protocol Specification Section 38.331: 5.5.5, Measurement Reporting. The UE has a process in Section 38.331 for reporting the power of signals from nearby base stations. These measurements received by the base station and the base station uses the measurements handoff decisions to determine when to hand off the UE to another base station or sector. An OOB power measurement IE, such as an ACLR IE, may be added to these reports, for example. The measurement reports are defined as being sent in control channel messages in the connected state. For these types of sessions, the control channel is referred to as a PUCCH, mentioned above. Alternatively, the IE may be added to any other report or sent separately.

At operation 614, the base station uses this OOB power measurement IE to determine a transmit power back-off for the base station to use in subsequent transmissions. Then at signal 616, the base station transmits another data traffic signal to the UE in accordance with the determined power back-off. While the UE is in connected status downlink data traffic will continue to be provided. Additional measurements may be made and the base station may continue to improve and adjust its transmit power.

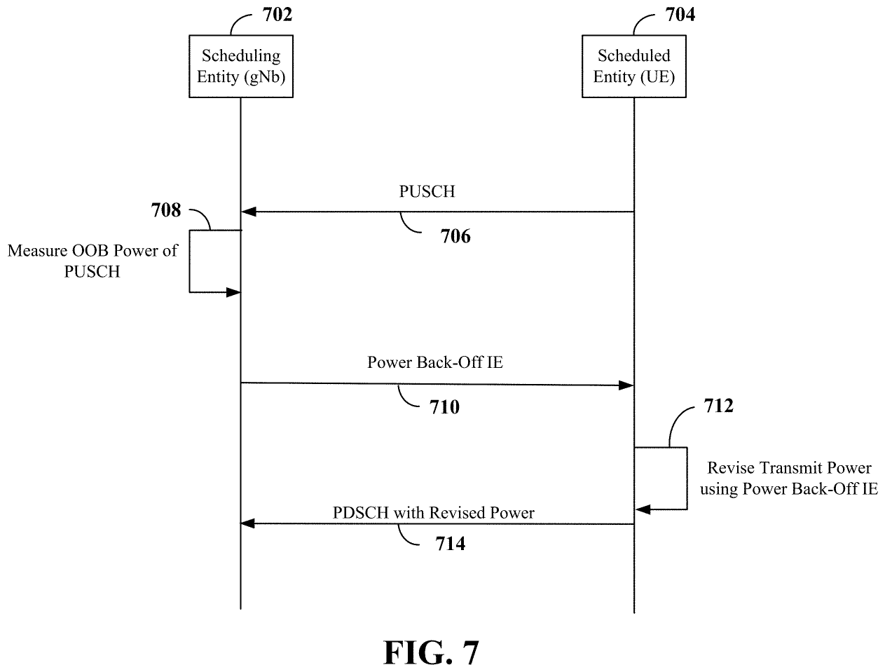

FIG. 7 is a signaling diagram illustrating an example of a base station controlling power back-off at a UE. The scheduling entity 702 (e.g., base station or gNb) is in wireless communication with a scheduled entity 704 (e.g., a UE). The scheduling entity 702 may correspond to any of the scheduling entities or base stations shown in FIGS. 1, 2, and 4. The scheduled entity 704 may correspond to any of the scheduled entities or UEs shown in FIGS. 1, 2, and 4 that includes a nonlinear RF power amplifier for transmission to the base station.

At signal 706, the UE sends an uplink data traffic signal to the base station, such as a PUSCH. This indicates a UE status of RRC_CONNECTED, or a similar active data traffic state.

At operation 708, the base station measures the OOB power of the uplink data traffic signal. Such a measurement may be made as described above for the UE or in any other way. As with the UE measurement, the base station is able to measure data traffic signal through the actual link between the UE and base station. These signals accurately reflect the UE, the traffic environment, and other factors at the time that the signals are being exchanged. The measurements are analyzed at the base station as with the UE measurement and the base station determines an appropriate adjustment for the UE power BO. This UE power BO may then be used to generate an IE to send to the UE.

At signal 710, the base station sends a power back-off IE to the UE. This IE may be sent in a control channel, such as PDCCH in any suitable message. As mentioned above Technical Specification 38.331: 5, Measurement Reporting, provides a suitable framework for sending such an IE. The IE serves as an instruction that the UE may use to adjust its power BO and may be a differential or absolute value. In one example, the power BO IE is a 5-bit integer value indicating an adjustment of ±16 steps, i.e. a range of [−16, +16) in a suitable increment, such as 0.5 dB. Using 5 bits allows a quick reduction or increase to be made for a power level that is far from an acceptable OOB range as shown, for example, in FIG. 5. Different formats and types of IEs may be used to suit different implementations.

At operation 712, the UE, in response to receiving the power back-off IE, adjusts the transmit power of the transmit power amplifier and at signal 714, the UE sends another uplink data traffic signal to the base station with the revised transmit power reflecting the power back-off that was received in signal 710.

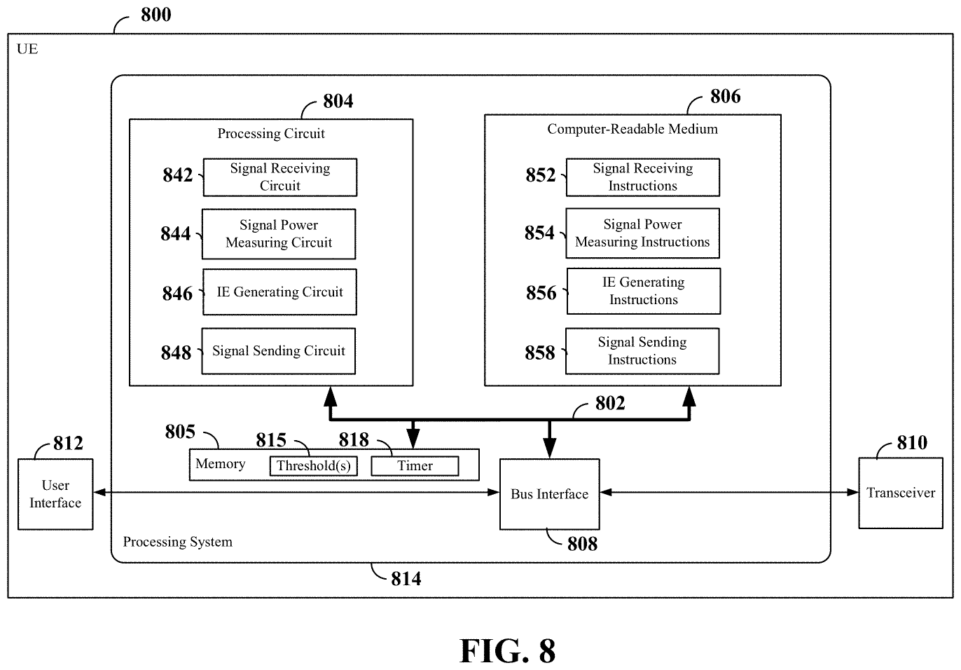

FIG. 8 is a block diagram illustrating an example of a hardware implementation for a scheduled entity or user equipment UE adapted to send OOB power measurements to a scheduling entity or base station. For example, the scheduled entity or UE 900 (e.g., managed mobile network node, RAN entity, or network node) may perform any of the functions illustrated and described in FIGS. 1, 2, 4, 6, and 7.

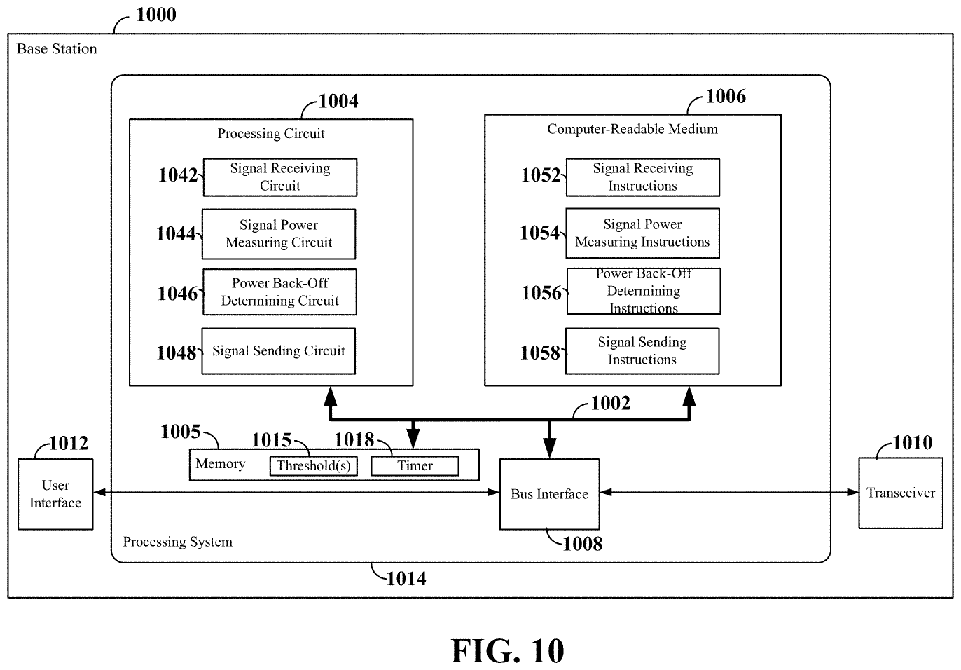

The scheduled entity or UE 800 may be implemented with a processing system 814 that includes one or more processing circuits 804. Examples of processing circuits 804 include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. In various examples, the scheduled entity or UE 800 may be configured to perform any one or more of the functions described herein. That is, the processing circuit 804, as utilized in the scheduled entity or UE 800, may be used to implement any one or more of the processes and procedures described in FIGS. 1, 2, 7 and 8 and further illustrated in the flow diagram of FIG. 10, to be discussed later.

In this example, the processing system 814 may be implemented with a bus architecture, represented generally by the bus 802. The bus 802 may include any number of interconnecting buses and bridges depending on the specific application of the processing system 814 and the overall design constraints. The bus 802 communicatively couples together various circuits including one or more processing circuits (represented generally by the processing circuit 804), a memory 805, and computer-readable media (represented generally by the computer-readable medium 806). The bus 802 may also link various other circuits such as timing sources, peripherals, voltage regulators, and power management circuits, which are well known in the art, and therefore, will not be described any further. A bus interface 808 provides an interface between the bus 802 and a transceiver 810. The transceiver 810 provides a communication interface or means for communicating with various other apparatus over a transmission medium. Depending upon the nature of the apparatus, a user interface 812 (e.g., keypad, display, speaker, microphone, joystick) may also be provided.

In some aspects of the disclosure, the processing circuit 804 may include a signal receiving circuit 842 configured for various functions, including, for example, receiving one or more directional or unidirectional beams to one or more base stations. A signal power measuring circuit 844 may serve to measure signal power in-band and out-of-band using appropriate techniques, such as ACI, ACLR, SNR, SINR, EVM, etc. An IE generating circuit 846 may serve to generate an IE representing the signal power measurements made by the signal power measurement circuit and prepare the IE for transmission in an appropriate packet.

The processing circuit 804 is responsible for managing the bus 802 and general processing, including the execution of software stored on the computer-readable medium 806. The software, when executed by the processor 804, causes the processing system 814 to perform the various functions described below for any particular apparatus. The computer-readable medium 806 and the memory 805 may also be used for storing data that is manipulated by the processor 804 when executing software.

One or more processing circuits 804 in the processing system may execute software. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software may reside on a computer-readable medium 806. The computer-readable medium 806 may be a non-transitory computer-readable medium. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software or instructions that may be accessed and read by a computer. The computer-readable medium 806 may reside in the processing system 814, external to the processing system 814, or distributed across multiple entities including the processing system 814. The computer-readable medium 806 may be embodied in a computer program product. By way of example, a computer program product may include a computer-readable medium in packaging materials. Those skilled in the art will recognize how best to implement the described functionality presented throughout this disclosure depending on the particular application and the overall design constraints imposed on the overall system.

In one or more examples, the computer-readable storage medium 806 may include signal receiving software or instructions 852, signal power measuring software or instructions 854, IE generating software or instructions 854, and signal sending instructions 858. Of course, in the above examples, the circuitry included in the processing circuit 804 is merely provided as an example, and other means for carrying out the described functions may be included within various aspects of the present disclosure, including but not limited to the instructions stored in the computer-readable storage medium 806, or any other suitable apparatus or means described in any one of the FIGS. 1 through 11 and utilizing, for example, the processes or algorithms described herein.

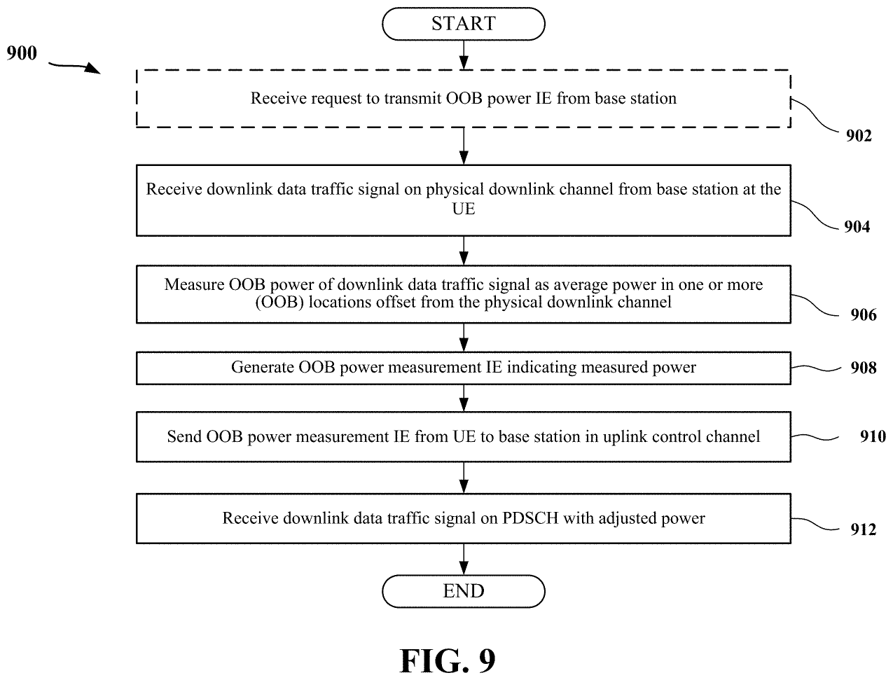

FIG. 9 is a flow chart illustrating an example method 900 operational at a scheduled entity or UE to facilitate reporting a power back-off power measurement to a base station. At block 902, a request to transmit an OOB power measurement IE is received from the base station. In one example, the request is received on a physical downlink control channel (PDCCH). The request may be for an immediate response or the request may indicate a periodicity for sending the OOB power measurement OOB IEs. The OOB power measurement IEs are then sent on a timer. The request may indicate the type of measurement to be made or a default measurement type may be used such as ACI/ACLR.

At block 904, a downlink data traffic signal is received on a physical downlink channel from a base station at the UE. The data traffic signal may be received on a PDSCH or any other suitable traffic channel.

At block 906, an out of band (OOB) power of the received downlink data traffic signal is measured for power back off. The receive OOB power may be measured in any suitable way. In one example, an average power of the downlink data traffic signal in one or more (OOB) locations of the wireless communication network is measured. The OOB locations are offset from the physical downlink channel.

At block 908, an OOB power measurement information element (IE) is generated that indicates the measured OOB power. The IE is configured for insertion into a transmission packet to the base station. For example, the IE may be placed in a suitable location in a PUCCH.

At block 910, the OOB power measurement IE is sent to the base station in the UL control channel, such as the PUCCH. When a request is received at 902, the IE is sent in response to the request. In some embodiments, the IE is sent periodically in response to a timer or other trigger. The base station may be configured to use the received IE to adjust a transmitter power back-off.

At block 912, a second downlink data traffic signal is received by the UE on the physical downlink channel, such as the PDSCH from the base station at the UE. The second downlink data traffic signal has a different transmit power in response to the OOB power measurement IE.

FIG. 10 is a block diagram illustrating an example of a hardware implementation for a scheduling entity or base station adapted to sending a power back-off IE to a UE. For example, the scheduling entity or base station 1000 (e.g., gNodeB, managed mobile network node, RAN entity, or network node) may perform any of the functions illustrated and described in FIGS. 1, 2, 7 and 8.

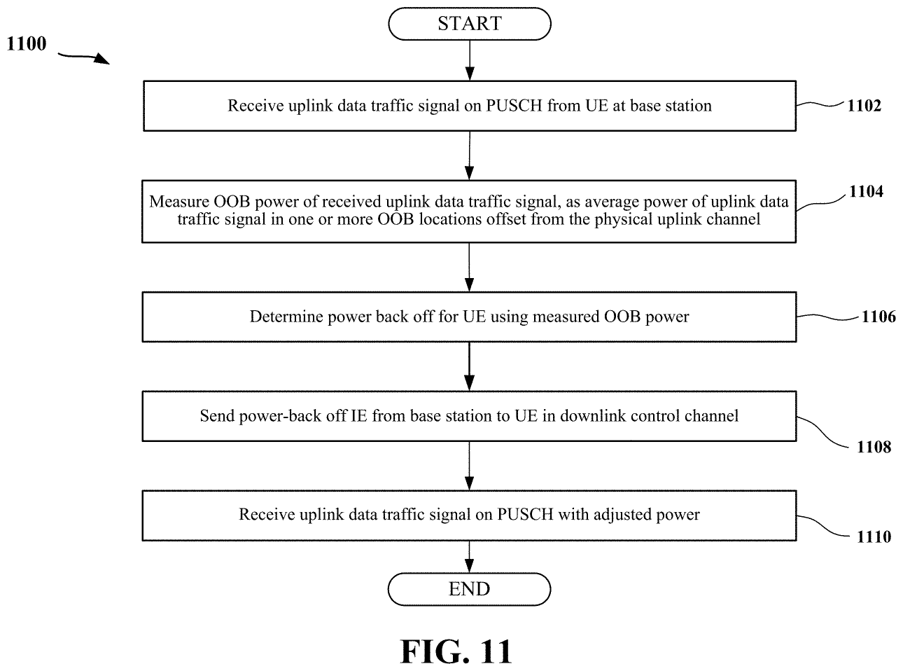

The scheduling entity or base station 1000 may be implemented with a processing system 1014 that includes one or more processing circuits 1004 of any of the types mentioned above with respect to FIG. 8 and configured to perform the various functionality described throughout this disclosure. That is, the processing circuit 1004, as utilized in the scheduling entity or base station 1000, may be used to implement any one or more of the processes and procedures described in FIGS. 1, 2, 7 and 9 and further illustrated in the flow diagram of FIG. 11, to be discussed later.

In this example, the processing system 1014 may be implemented with a bus architecture, represented generally by the bus 1002. The bus 1002 may include any number of interconnecting buses and bridges depending on the specific application of the processing system 1014 and the overall design constraints. The bus 1002 communicatively couples together various circuits including one or more processing circuit (represented generally by the processing circuit 1004), a memory 1005, and computer-readable media (represented generally by the computer-readable medium 1006). The bus 1002 may also link various other circuits such as timing sources, peripherals, voltage regulators, and power management circuits, which are well known in the art, and therefore, will not be described any further. A bus interface 1008 provides an interface between the bus 1002 and a transceiver 1010. The transceiver 1010 provides a communication interface or means for communicating with various other apparatus over a transmission medium. Depending upon the nature of the apparatus, a user interface 1012 (e.g., keypad, display, speaker, microphone, joystick) may also be provided.

In some aspects of the disclosure, the processing 1004 may include a signal receiving circuit 1042 configured to receive any of the signal discussed herein including data traffic and control signals. A signal power measuring circuit 1044 may serve to measure in-band and out-of-band power, interference, and distortion. A power back-off determining circuit 1046 may serve to determine a suitable power back off to be applied to a connected UE. The circuit may then configure that power back-off as an IE to be included in a control channel packet. A signal sending circuit 1048 may serve to send the power back-off IE to the UE.

The processing circuit 1004 is responsible for managing the bus 1002 and general processing, including the execution of software stored on the computer-readable medium 1006. The software, when executed by the processor 1004, causes the processing system 1014 to perform the various functions described below for any particular apparatus. The computer-readable medium 1006 and the memory 1005 may also be used for storing data that is manipulated by the processor 1004 when executing software.

One or more processing circuits 1004 in the processing system may execute software construed as described above with respect to FIG. 8. The software may reside on a computer-readable medium 1006. The computer-readable medium 1006 may be a non-transitory computer-readable medium of any type as described above with respect to FIG. 8 that may reside in the processing system 1014, external to the processing system 1014, or distributed across multiple entities including the processing system 1014. The computer-readable medium 1006 may be embodied in a computer program product as described above with respect to FIG. 8. Those skilled in the art will recognize how best to implement the described functionality presented throughout this disclosure depending on the particular application and the overall design constraints imposed on the overall system.

In one or more examples, the computer-readable storage medium 1006 may include signal receiving software or instructions 1052, signal power measuring software or instructions 1054, power back-off determining software or instructions 1056, and signal sending instructions 1058. Of course, in the above examples, the circuitry included in the processing circuit 1004 is merely provided as an example, and other means for carrying out the described functions may be included within various aspects of the present disclosure, including but not limited to the instructions stored in the computer-readable storage medium 1006, or any other suitable apparatus or means described in any one of the FIGS. 1 through 11 and utilizing, for example, the processes or algorithms described herein.

FIG. 11 is a flow chart illustrating an example method 1100 operational at a scheduling entity or a base station to facilitate closed loop power back-off control of a UE. At block 1102, an uplink data traffic signal is received on a physical uplink channel, such as a PUSCH from a UE at a base station.

At block 1104, the base station measures an out of band (OOB) power of the received uplink data traffic signal. The OOB power may be an average power of the uplink data traffic signal in one or more OOB locations of the wireless communication network that are offset from the physical uplink channel.

At block 1106, a power back-off is determined for the UE using the OOB power measurement and optionally also using the adjacent channel loading.

At block 1108, a power back-off information element is sent by the base station to the UE. The IE indicating an amount of UE transmit power amplifier power back off. The UE may then use this IE to adjust its transmit power. The IE may be sent in a downlink control channel, such as PDCCH.

At block 1110, a second uplink data traffic signal is received on the physical uplink channel from the UE. The second uplink data traffic signal has a different transmit power in response to the power back-off IE.

Several aspects of a wireless communication network have been presented with reference to an exemplary implementation. As those skilled in the art will readily appreciate, various aspects described throughout this disclosure may be extended to other telecommunication systems, network architectures and communication standards.

By way of example, various aspects may be implemented within other systems defined by 3GPP, such as Long-Term Evolution (LTE), the Evolved Packet System (EPS), the Universal Mobile Telecommunication System (UMTS), and/or the Global System for Mobile (GSM). Various aspects may also be extended to systems defined by the 3rd Generation Partnership Project 2 (3GPP2), such as CDMA2000 and/or Evolution-Data Optimized (EV-DO). Other examples may be implemented within systems employing IEEE 802.11 (Wi-Fi), IEEE 802.16 (WiMAX), IEEE 802.20, Ultra-Wideband (UWB), Bluetooth, and/or other suitable systems. The actual telecommunication standard, network architecture, and/or communication standard employed will depend on the specific application and the overall design constraints imposed on the system.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. For instance, a first object may be coupled to a second object even though the first object is never directly physically in contact with the second object. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features and/or functions illustrated in FIGS. 1-11 may be rearranged and/or combined into a single component, step, feature, or function or embodied in several components, steps, or functions. Additional stages, components, steps, and/or functions may also be added without departing from novel features disclosed herein. The apparatus, devices, and/or components illustrated in FIGS. 1, 2, 4-6, 8 and 11 may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present stages of the various steps in a sample order and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an stage in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b, and c. All structural and functional equivalents to the stages of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

What is claimed is:

1. A method of reporting an out-of-band power measurement by a user equipment (UE) in a wireless communication network:
receiving a downlink data traffic signal on a physical downlink channel from a base station at the UE;
measuring an out of band (OOB) power of the received downlink data traffic signal, the receive OOB power comprising an average power of the downlink data traffic signal in one or more (OOB) locations of the wireless communication network offset from the physical downlink channel;
generating an OOB power measurement information element (IE) indicating the measured OOB power; and
sending the OOB power measurement IE to the base station in an uplink control channel.

2. The method of claim 1, further comprising receiving a second downlink data traffic signal on the physical downlink channel from the base station at the UE, wherein the second downlink data traffic signal has a different transmit power in response to the OOB power measurement IE.

3. The method of claim 1, further comprising receiving a request to transmit an OOB power measurement IE from the base station before receiving the downlink data traffic signal and wherein sending the OOB power measurement IE is in response to the received request.

4. The method of claim 3, wherein the request is transmitted in a downlink control channel when the UE is in a connected radio resource control (RRC) status.

5. The method of claim 1, wherein receiving the downlink data traffic signal is performed when the UE is in a connected RRC status.

6. The method of claim 1, wherein sending the OOB power measurement IE comprises sending the OOB power measurement IE with neighboring cell receive power measurements for handoff.

7. The method of claim 1, wherein measuring the OOB power further comprises determining a ratio of an average power of the downlink data traffic signal in the physical downlink channel divided by an average power leakage into out-of-band locations offset from the physical downlink channel.

8. The method of claim 7, wherein the average power of the downlink data traffic signal comprises an average power of resource elements carrying physical downlink shared channel ports to the UE within a selected frequency width for a selected duration.

9. The method of claim 8, wherein the average power leakage into out-of-band locations comprises an average power in multiple out-of-band locations for the selected frequency width for the selected duration, the power in each location being scaled for a distance in frequency from a frequency of the downlink data traffic signal.

10. The method of claim 7, wherein determining the ratio comprises measuring the average power within a selected frequency range above and below a center frequency of the downlink data traffic signal and measuring the average power within the selected frequency range above and below the out-of-band locations, wherein the physical downlink channel has an allocated bandwidth, wherein the out-of-band locations are determined as a frequency distance from a frequency edge of the allocated bandwidth of the center frequency.

11. The method of claim 7, wherein the measured average power in each of the multiple out-of-band locations is transmitted in the OOB power measurement IE.

12. The method of claim 1, wherein measuring the OOB power further comprises measuring in-band distortion of the downlink data traffic signal.

13. The method of claim 12, wherein measuring in-band distortion comprises measuring error vector magnitude.

14. A user equipment (UE) in a wireless communication network, comprising:
a wireless transceiver comprising a nonlinear power amplifier;
a memory; and
a processor communicatively coupled to the wireless transceiver and the memory, wherein the processor is configured to:
receive a downlink data traffic signal on a physical downlink channel from a base station at the UE;
measure an out of band (OOB) power of the received downlink data traffic signal, the receive OOB power comprising an average power of the downlink data traffic signal in one or more (OOB) locations of the wireless communication network offset from the physical downlink channel;
generate an OOB power measurement information element (IE) indicating the measured OOB power; and
send the OOB power measurement IE to the base station in an uplink control channel.

15. The UE of claim 14, the processor further configured to receive a second downlink data traffic signal on the physical downlink channel from the base station at the UE, wherein the second downlink data traffic signal has a different transmit power in response to the OOB power measurement IE.

16. The UE of claim 14, the processor further configured to receive a request to transmit an OOB power measurement IE from the base station before receiving the downlink data traffic signal and wherein sending the OOB power measurement IE is in response to the received request.

17. The UE of claim 16, wherein the request is transmitted in a downlink control channel when the UE is in a connected radio resource control (RRC) status.

18. A method of controlling transmit power back off in a user equipment (UE) in a wireless communication network:
receiving an uplink data traffic signal on a physical uplink channel from a UE at a base station;
measuring an out of band (OOB) power of the received uplink data traffic signal, the OOB power comprising an average power of the uplink data traffic signal in one or more OOB locations of the wireless communication network offset from the physical uplink channel;
determining a power back for the UE using the measured OOB power; and
sending a power back off information element (1E) to the UE in a downlink control channel, the power back off 1E indicating an amount of UE transmit power amplifier power back off.

19. The method of claim 18, wherein receiving the uplink data traffic signal is performed when the UE is in a connected Radio Resource Control (RRC) status.

20. The method of claim 18, wherein the power back off 1E comprises an integer indicating steps of 0.5 dB.

21. The method of claim 18, wherein measuring the OOB power comprises:
measuring a first average power of the uplink beam;
measuring a second average power leakage into OOB locations from the uplink beam; and
determining a ratio of the first average power divided by the second average power.

22. The method of claim 21, wherein measuring the first average power comprises measuring an average power of resource elements carrying physical uplink shared channel (PUSCH) ports for the UE.

23. The method of claim 22, wherein measuring the second average power comprises measuring an average power in OOB locations and scaling the average power measured in each location based on offset from the uplink data traffic channel.

24. A base station in a wireless communication network, comprising:
a wireless transceiver comprising a nonlinear power amplifier;
a memory; and
a processor communicatively coupled to the wireless transceiver and the memory, wherein the processor is configured to:
receive an uplink data traffic signal on a physical uplink channel from a UE at the base station;
measure an out of band (OOB) power of the received uplink data traffic signal, the OOB power comprising an average power of the uplink data traffic signal in one or more OOB locations of the wireless communication network, offset from the physical uplink channel;
determine a power back for the UE using the measured OOB power; and
send a power back off information element (IE) to the UE in a downlink control channel, the power back off IE indicating an amount of UE transmit power amplifier power back off.

25. The base station of claim 24, wherein receiving the uplink data traffic signal is performed when the UE is in a connected Radio Resource Control (RRC) status.

26. The base station of claim 24, wherein measuring the OOB power comprises:
measuring a first average power of the uplink beam;
measuring a second average power leakage into OOB locations from the uplink beam; and
determining a ratio of the first average power divided by the second average power.
